(19) United States
(12) Patent Application Publication
(10) Pub. No.: US 2002/0133752 A1
(43) Pub. Date: Sep. 19, 2002

(54) Component/web service operational profile auto-sequencing

(76) Inventor: Wesley Hand, Londonderry, NH (US)

Correspondence Address: DALY, CROWLEY & MOFFORD, LLP, SUITE 101, 275 TURNPIKE STREET, CANTON, MA, 02021-2310, US

(21) Appl. No.: 10/098,066

(22) Filed: Mar. 13, 2002

Related U.S. Application Data
(60) Provisional application No. 60/277,077, filed on Mar. 19, 2001.

(51) Int. Cl. G06F 9/44; H03K 19/003; H02H 3/05; H05K 10/00; H04B 1/74; H04L 1/22

(52) U.S. Cl. 714/38; 717/124

(57) ABSTRACT

The present invention produces an operational profile of how a software component under test will be utilized during normal operation. This profile could apply to either its functional or its load requirements and includes information relating to the number of test sequences to be generated, the maximum number of method calls to be included in a test sequence and a likelihood value representing the likelihood that one method will follow another method in a test sequence. From this profile, a set of sequences of method calls are automatically generated such that the component can be tested based on the profile.

### CROSS REFERENCE TO RELATED APPLICATIONS

This application claims priority under 35 U.S.C. §119(e) to provisional patent application serial No. 60/277,077 filed Mar. 19, 2001; the disclosure of which is incorporated by reference herein.

### BACKGROUND OF THE INVENTION

Componentized software is software that is designed to allow different pieces of the application, known as “software components” or “objects”, to be created separately but still to have the objects work together. The objects have standard interfaces that are understood and accessed by other objects. Some parts of these interfaces are enforced by the software language. If the interfaces are not used, the software objects will not be able to work with other objects.

An example of a software component is an Enterprise Java Bean™ software component (EJB). EJBs are written in the JAVA language, which is intended to be “platform independent.” Platform independent means that an application is intended to perform the same regardless of the hardware and operating system on which it is operating. Platform independence is achieved through the use of a “container.” A container is software that is designed for a specific platform. It provides a standardized environment that ensures the application written in the platform independent language operates correctly. The container is usually commercially available software and the application developer will buy the container rather than create it. Other software component types are also known. Examples of these include COM (Component Object Model), COM+, CORBA (Common Object Request Broker Architecture), and DCOM (Distributed Component Object Model) among others.

Tools are available to automate the execution of tests on applications. For example, Empirix Inc. of Waltham, Mass., provides a product called e-Load. This tool simulates load on an application under test and provides information about the performance of the application. However, this tool does not provide information about the software components that make up the application. Another tool known as Bean-test TM also available from Empirix Inc. of Waltham, Mass., tests individual software components.

Automatic test generation tools, such as TestMaster available from Empirix Inc. of Waltham, Mass., are also available. Tools of this type provide a means to reduce the manual effort of generating a test. TestMaster works from a state model of the application under test. Such an application is very useful for generating functional tests during the development of an application. Once the model of the application is specified, TestMaster can be instructed to generate a suite of tests that can be tailored for a particular task such as to fully exercise some portion of the application that has been changed. Model based testing is particularly useful for functional testing of large applications, but is not fully automatic because it requires the creation of a state model of the application being tested. While all of the above-described tools have proved to be useful for testing software components and applications that include software components, they are not able to test Web Services.

A Web Service is programmable application logic that is accessible using standard Internet protocols such as Hypertext Transfer Protocol (HTTP). Web Services represent black-box functionality that can be reused without worrying about how the service is implemented. Web Services use a standard data format such as Extensible Markup Language (XML). A Web Service interface is defined in terms of the messages the Web Service accepts and produces. Users of the Web Service can be utilizing any platform in any programming language as long as they can create and consume the messages defined for the Web Service interface.

Similar to software components, Web Services provide functionality that can be used multiple times and by multiple different applications running on multiple different systems. Web services are accessed via web protocols such as Hypertext Transfer Protocol (HTTP) and by data formats such as Extensible Markup Language (XML). A Web Service interface is defined in terms of messages the Web Service can accept and generate. Users of the Web Service can be implemented on any platform and in any programming language, as long as they can create and consume the messages defined for the particular Web Service being utilized.

A protocol has been defined for performing information interchange with Web Services. This protocol is the Simple Object Access Protocol (SOAP). Typically objects are platform dependent, thus an object created on one platform cannot be used by software running on other platforms. Some distributed object technologies require the use of specific ports to transmit their data across the Internet (for example, DCOM uses port 135). Most firewalls prevent the use of all ports except for port 80, which is the default port for HTTP communications.

SOAP provides a platform independent way to access and utilize Web Services located on different distributed systems, and allows communications through firewalls. SOAP utilizes XML, and XML documents are transported via HTTP through firewalls.

SOAP messages are sent in a request/response manner. SOAP defines an XML structure to call a Web Service and to pass parameters to the Web Service. SOAP further defines an XML structure to return values that were requested from the Web Service. SOAP further defines an XML structure for returning error values if the Web Service cannot execute the desired function.

An example of a Web Service can be described as follows. A system has an application residing thereon. Part of the application requires use of a particular Web Service that may be located on a remote machine. The application requesting the use of the particular Web Service composes a SOAP message and sends the message to the server. The message travels across a network such as the Internet, and is received by the remote server that has the requested Web Service residing thereon. Once the SOAP message has been received by the server, the Web Service is called. Once the Web Service has finished processing, a SOAP message is prepared to be sent back to the application. The message is sent across the Internet to the system where it is processed by the application. In such a manner the Web Service is utilized by an application on a system remotely located from the Web Service. As described above SOAP allows systems to be highly distributed. Accordingly, developers are able to rely on the expertise and existing proven code of other developers to more quickly build more reliable systems.

For purposes of this description, the term software component will be used to include both software components such as Enterprise Java Beans™ and other components, some of which are described above, as well as Web Services such as the .net Web Service. A software component is tested by making sequences of calls to the methods (routines) of the component. As these methods are executed, the software component returns results via a return value or output parameter. These resulting values are validated against a set of criteria and any failures are reported to the user. In order to properly test a software component, whether it is for functional testing or for load testing, a test engineer must provide one or more method calls to the methods of the software component being tested.

There have been attempts to automatically generate sequences of method calls for the software component under test. Each of these automatic generation methods has associated drawbacks.

One approach to automatically generating test sequences of method calls for testing a software component involves randomly generating the sequence of method calls. This is problematic because invalid sequences may be generated which defeats the purpose of testing the software component. Further, any valid sequences that happen to be generated may not represent typical operational behavior of the software component, thus providing little value.

Another prior art approach to automatically generating test sequences for software components involves creating a model of the behavior of the component using some modeling language such as UML. This approach has the disadvantage in that creating a reliable model that can be used for test generation has also proven to be a difficult and time-consuming task.

In view of the foregoing it would be desirable to provide a method for providing a model of a software component's behavior that can be used to automatically generate test programs for testing the software component. It would be further desirable if the method were not time-consuming or labor-intensive.

### SUMMARY OF THE INVENTION

With the foregoing background in mind, it is an object of the present invention to produce an operational profile of how the software component under test will be utilized during normal operation. This profile could apply to either the component's functional requirements or the component's load requirements. The profile includes information relating to the number of test sequences to be generated, the maximum number of method calls to be included in each test sequence and a likelihood value representing the likelihood that one method will follow another method in a test sequence. From this profile, a set of sequences of method calls are automatically generated such that the component can be tested based on the profile.

### BRIEF DESCRIPTION OF THE DRAWINGS

The invention will be better understood by reference to the following more detailed description and accompanying drawings in which:

FIG. 1 is a screen shot showing the user interface for setting up a profile for the generation of test sequences in accordance with the present invention; and

FIG. 2 is a flow chart showing the steps involved in the present method for automatically generating test sequences for testing a software component.

### DETAILED DESCRIPTION

The present invention allows the test programmer to provide an operational profile of how the software component under test will be utilized during normal operation. This profile could apply to either the components functional or load requirements. From this profile, a set of sequences of method calls is automatically generated such that the component is tested based on that profile.

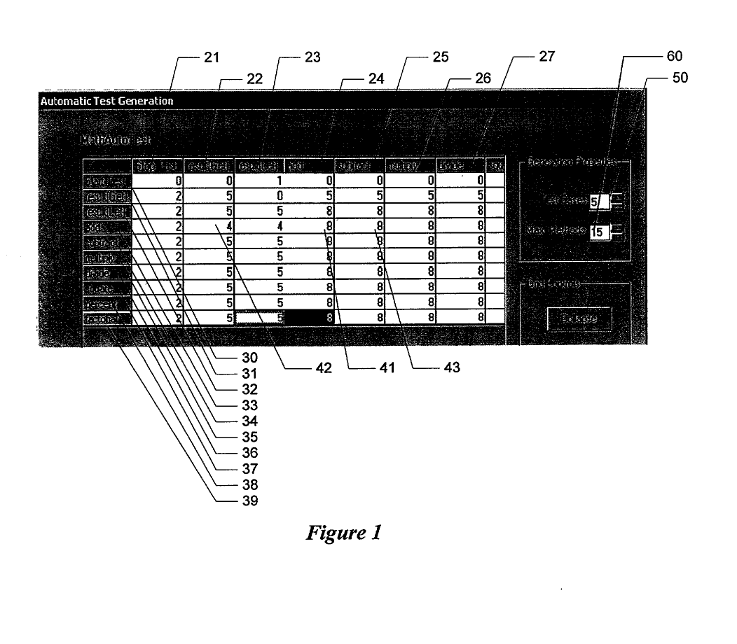

This is accomplished by the test engineer filling in a grid similar to the one shown in FIG. 1. In the described embodiment three pieces of information or parameters are provided by the test engineer to the grid 10. While three parameters are described, it should be understood that more then or less then three parameters could also be utilized as part of the present method. The first information input by the test engineer is the number of sequences (Test Cases) 50 to be generated. The more sequences that are created, the more closely the test will represent the specified profile. While FIG. 1 shows 5 test cases are to be generated, any number of test cases could be used.

The second parameter provided by the test engineer is the maximum number of method calls 60 to be put into each sequence. In this example the test engineer has determined that the five test cases will contain a maximum of fifteen method calls each. While fifteen method calls per test sequence are shown here, any number of method calls could be selected.

The third parameter is a matrix containing numerical likelihood values corresponding to the likelihood of one method following another method in a test sequence. Each of the methods of the component(s) under test is placed on both the vertical and horizontal axis of the grid. As shown in FIG. 1, the different methods of the software component, in this example result(Get) 22, result(Let) 23, add 24, subtract 25, multiply 26, divide 27 and others which are not shown are listed along a horizontal axis. Similarly the methods are also listed along a vertical axis of grid 10. These include result(Get) 32, result(Let) 33, add 34, subtract 35, multiply 36, divide 37, square 38, percent 39 and factorial 40. Additionally, a STOP TEST 21 method is included along the horizontal axis and a START TEST 31 method is included along the vertical axis.

An integer value is then placed in each cell of the grid to indicate the likelihood of the corresponding method on the horizontal axis following the corresponding method on the vertical axis. The likelihood values are relative to all other cells in the same row. For example, it is twice as likely that a call to another add method 24 will follow an add method call 33 (likelihood value of 8 in cell 41) then it is for a result method call 22 to follow the add method call 33 (likelihood value of 4 in cell 42). This can be seen by going to the row headed by the add method and scanning across to the result column and the add column. Notice that the likelihood number for the add method (8) is twice as big as the likelihood value for the result method (4). By this same logic, a subtract method call 25 is just as likely to follow an add method call 33 as is another add method call 24 because its likelihood value (8) is the same. From this operational profile, a set of test sequences is automatically generated so as to match that profile.

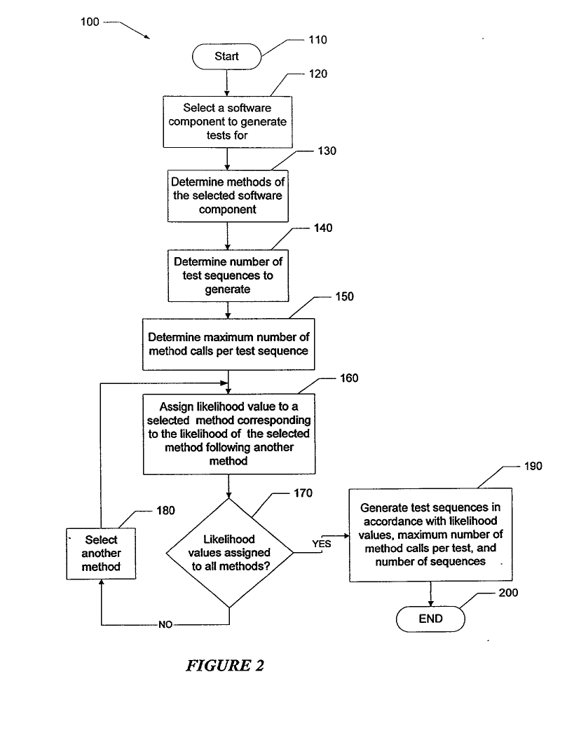

A flow chart of the presently disclosed method is depicted in FIG. 2. The rectangular elements are herein denoted “processing blocks” and represent computer software instructions or groups of instructions. The diamond shaped elements, are herein denoted “decision blocks,” represent computer software instructions, or groups of instructions which affect the execution of the computer software instructions represented by the processing blocks.

Alternatively, the processing and decision blocks represent steps performed by functionally equivalent circuits such as a digital signal processor circuit or an application specific integrated circuit (ASIC). The flow diagrams do not depict the syntax of any particular programming language. Rather, the flow diagrams illustrate the functional information one of ordinary skill in the art requires to fabricate circuits or to generate computer software to perform the processing required in accordance with the present invention. It should be noted that many routine program elements, such as initialization of loops and variables and the use of temporary variables are not shown. It will be appreciated by those of ordinary skill in the art that unless otherwise indicated herein, the particular sequence of steps described is illustrative only and can be varied without departing from the spirit of the invention. Thus, unless otherwise stated the steps described below are unordered meaning that, when possible, the steps can be performed in any convenient or desirable order.

Referring now to FIG. 2, a flow chart of the present method 100 is shown. The method starts at step 110 wherein initialization is performed. This step may include initializing files, counters, or the like. Following step 110, step 120 is executed.

Step 120 comprises selecting a software component to generate tests for. As described above, the method is applicable for any type of software component including EJBs, COM, CORBA, COM+, DCOM and net software components (including web services).

Following selection of the software component, as shown in step 130, the methods of the component are determined. For example, a component titled MATH may include an add method, a subtract method, a multiply method and a divide method. Once the methods of the component have been determined, step 140 is executed.

Step 140 involves determining the number of test sequences to generate. A single test sequence includes calls to various methods of the component. For example, a test sequence for the MATH component may include a first call to the add method, followed by a call to the subtract method, followed by a call to the multiply method followed by a call to the result(Get) method. The test operator determines the number of test sequences to be generated. The larger the number of test sequences to be generated, the more closely the test will represent the specified profile.

Step 150 is executed next. At step 150 the maximum number of method calls per test sequence is determined. Similar to step 140, the test operator determines the maximum number of method calls per test sequence. Following step 150, step 160 is executed.

Step 160 comprises assigning a likelihood value for a method corresponding to the likelihood of the selected method following another method of the component. The test operator selects these likelihood values.

Step 170 involves determining if likelihood values for all the methods of the component have been determined with respect to all of the other methods of the component. If not, step 180 is executed wherein another method is selected, then step 160 is executed again. This process of steps 160, 170 and 180 is repeated until likelihood values have been assigned to all methods with respect to all other methods of the component.

Once likelihood values have been assigned to all methods with respect to all other methods of the component step 190 is executed. At step 190 test sequences are generated in accordance with the likelihood values, the maximum number of method calls per test sequence and the number of test sequences to generate.

Following step 190, the process ends as shown in step 200. At this point the generated test sequences can be used to test the software component.

As described above the present invention generates a set of sequences of method calls that a software component can be tested. The resulting test sequences are based on a profile of the component. This profile could apply to either its functional or its load requirements and includes information relating to the number of test sequences to be generated, the maximum number of method calls to be included in a test sequence and a likelihood value representing the likelihood that one method will follow another method in a test sequence.

Having described preferred embodiments of the invention it will now become apparent to those of ordinary skill in the art that other embodiments incorporating these concepts may be used. Additionally, the software included as part of the invention may be embodied in a computer program product that includes a computer useable medium. For example, such a computer usable medium can include a readable memory device, such as a hard drive device, a CD-ROM, a DVD-ROM, or a computer diskette, having computer readable program code segments stored thereon. The computer readable medium can also include a communications link, either optical, wired, or wireless, having program code segments carried thereon as digital or analog signals. Accordingly, it is submitted that that the invention should not be limited to the described embodiments but rather should be limited only by the spirit and scope of the appended claims.

What is claimed is:

1. A method for generating at least one test sequence for testing a software component having one or more methods comprising:
identifying a software component to be tested;
determining the methods of the software component;
establishing a likelihood value for each method of a software component corresponding to a likelihood of the method following another method of said software component; and
generating at least one test sequence in accordance with the likelihood value for each method.

2. The method of claim 1 further comprising providing a number of test sequences to be generated.

3. The method of claim 1 further comprising establishing a maximum number of method calls to be included in each test sequence.

4. The method of claim 1 wherein the software component is selected from the group including an Enterprise Java Bean, COM, COM+, CORBA, DCOM, and .net.

5. The method of claim 1 wherein said establishing comprises providing a grid, said grid having each method of the component along a horizontal axis and each method of the component along a vertical axis, and wherein each cell of the grid contains a likelihood value that a corresponding method on the horizontal axis will follow a corresponding method on the vertical axis.

6. The method of claim 5 wherein said establishing further comprises providing a Start Test method along the vertical axis.

7. The method of claim 5 wherein said establishing further comprises providing a Stop Test method along the horizontal axis.

8. A computer program product for generating at least one test sequence for testing a software component having one or more methods comprising a computer usable medium having computer readable code thereon, including program code comprising:
instructions for determining the methods of a software component;
instructions for establishing a likelihood value for each method of the software component corresponding to a likelihood of the method following another method of said software component; and
instructions for generating at least one test sequence in accordance with the likelihood value for each method.

9. The computer program product of claim 8 further comprising instructions for providing a number of test sequences to be generated.

10. The computer program product of claim 8 further comprising instructions for providing a maximum number of method calls for each test sequence.

11. The computer program product of claim 8 further comprising instructions for providing a grid, said grid having each method of the component along a horizontal axis and each method of the component along a vertical axis, and wherein each cell of the grid contains a likelihood value that a corresponding method on the horizontal axis will follow a corresponding method on the vertical axis.

12. The computer program product of claim 11 further comprising instructions for providing a Start Test method along the vertical axis.

13. The computer program product of claim 11 further comprising instructions for providing a Stop Test method along the horizontal axis.
